(19) United States
(12) Patent Application Publication
(10) Pub. No.: US 2006/0131757 A1
(43) Pub. Date: Jun. 22, 2006

(54) Light emitting module

(75) Inventors: Wen-Hsiung Yu, Nantou (TW); Ming-Che Wu, Chiayi (TW); Hsi-Che Huang, Keelung (TW); Cheng-Yi Hsu, Changhua (TW); Mao-Jen Wu, Kaohsiung (TW)

Correspondence Address: MADSON & AUSTIN;GATEWAY TOWER WEST, SUITE 900, 15 WEST SOUTH TEMPLE, SALT LAKE CITY, UT, 84101, US

(73) Assignee: Neostones MicroFabrication Corporation

(21) Appl. No.: 11/095,799

(22) Filed: Mar. 31, 2005

(30) Foreign Application Priority Data
Dec. 16, 2004 (CN) 2004101022273

(51) Int. Cl. H01L 23/48

(52) U.S. Cl. 257/778

(57) ABSTRACT

A light emitting module includes a substrate, a driving circuit chip, a light emitting element and a connector. By providing the connector with conductive bumps and arranging it as a flip chip to contact the conductive bumps with bond pads of the driving circuit chip and the light emitting element, a light emitting module with a reduced bonding pitch but reliable performance can be produced. Alternatively, it can be the driving circuit chip instead of the connector functioning as a flip chip. The driving circuit chip includes conductive bumps in contact with bond pads of the light emitting element and the connector.

### FIELD OF THE INVENTION

The present invention relates to a light emitting module, and more particularly to a light emitting module of an optoelectronic device for use in an image processing apparatus.

### BACKGROUND OF THE INVENTION

Light emitting modules, for example light emitting diode (LED) arrays, are widely used in optoelectronic devices of image processing apparatus such as printing machines, copying machines or scanning machines.

Referring to FIGS. 1 and 2, a packaged structure of a conventional LED module is partially shown. The LED module comprises a substrate 111, a plurality of light emitting elements 121 adhered to the substrate 111 with adhesive material 151 and separate from one another for independently emitting light, and a plurality of driving circuit chips 131 adhered to the substrate 111 with adhesive material 152 and separate from one another for independently driving said light emitting elements 121. The driving circuit chips 131 are electrically connected to the light emitting elements 121 via bonding wires 141, respectively. The driving circuit chips 131 are further electrically connected to other elements on the substrate 111 via bonding wires 161.

Since the light emitting elements 121 and the driving circuit chips 131 are bonded to each other one on one with individual gold wires, there would be numerous wire bonding operations required to be performed in the manufacturing process of a light emitting module. Take an A4 size LED printer head for example. In order to accomplish a resolution of 600 dpi, about 5,000 I/O sites need be formed on the light emitting elements 121 and the driving circuit chips 131. In other words, about 5,000 wire boding operations need be performed in order to form the metal wires 141. The large number of wire bonding operations complicates the manufacturing process of the light emitting diode and thus adverse to the yield and manufacturing cost. Currently, the reliable bonding pitch in a pad is about 100 micrometers. If the wiring density is further increased, the pitch will become less so as to adversely affect the reliability of the device.

### SUMMARY OF THE INVENTION

Therefore, the present invention provides a light emitting module with a reduced bonding pitch but reliable performance.

The present invention relates to a light emitting module, which comprises a substrate; a driving circuit chip attached to the substrate; a light emitting element attached to the substrate; and a flip-chip connector having a plurality of conductive bumps and wires for electrically connecting to both the driving circuit chip and the light emitting element when the flip-chip connector is placed above the driving circuit chip and the light emitting element as a bridge, thereby communicating the driving circuit chip with the light emitting element.

Preferably, the substrate is a printed circuit board or a ceramic substrate.

Preferably, the light emitting element is a light emitting diode, a liquid crystal display element or a laser light source element.

Preferably, the light emitting module is used in a printing machine, a copying machine or a scanning machine.

In an embodiment, the conductive bumps of the flip-chip connector are in direct contact with bond pads of the driving circuit chip and bond pads of the light emitting element.

In an embodiment, the flip-chip connector is a circuit board formed thereon the conductive bumps and wires.

The present invention also relates to a light emitting module, which comprises a substrate, a driving circuit chip, a light emitting element and a bridge connector. The driving circuit chip has a first surface attached to the substrate and a second surface having thereon a plurality of first contacts. The light emitting element has a third surface attached to the substrate and a fourth surface having thereon a plurality of second contacts. The bridge connector comprises a main body and a plurality of wires supported by the main body. The wires electrically connect the first contacts to the second contacts one on one when the bridge connector is coupled to the driving circuit chip and the light emitting element, thereby communicating the driving circuit chip with the light emitting element.

In an embodiment, the bridge connector further comprises a plurality of conductive bumps electrically connected to the wires, and the bridge connector is coupled to the driving circuit chip and the light emitting element by contacting the conductive bumps with the first contacts and the second contacts.

In an embodiment, the bridge connector is a flip-chip connector, and the conductive bumps and the wires are arranged on the bottom surface of the main body.

In an embodiment, the conductive bumps and the wires are included in a lithographically etched pattern formed on the bottom surface of the main body.

In an embodiment, the driving circuit chip has third contacts wired to the substrate on the second surface.

In an embodiment, the driving circuit chip and the light emitting element are attached to the substrate with adhesive material.

A pitch between two adjacent ones of the wires can be made to less than 50 micrometers according to the present invention.

The present invention further relates to a light emitting module, which comprises a substrate; a light emitting element attached to the substrate; a connector attached to the substrate; and a flip-chip type driving circuit chip having a main circuit for controlling the light emitting element and a plurality of conductive bumps electrically connecting to both the light emitting element and the connector when the flip-chip type driving circuit chip is placed above the light emitting element and the connector as a bridge, thereby communicating the main circuit with the light emitting element and the connector.

Preferably, the flip-chip type driving circuit is a circuit board formed thereon the main circuit and the conductive bumps electrically interconnected.

Preferably, the light emitting element and the connector further comprise a plurality of bond pads in direct contact with the conductive bumps of the flip-chip type driving circuit chip, respectively, when the flip-chip type driving circuit chip is placed above the light emitting element and the connector as the bridge.

In an embodiment, the conductive bumps are formed by a lithographic and etching process along with the main circuit.

In an embodiment, the connector comprises a plurality of bond pads wired to the substrate.

A pitch between two adjacent ones of the conductive bumps can be made less than 50 micrometers according to the present invention.

The above contents of the present invention will become more readily apparent to those ordinarily skilled in the art after reviewing the following detailed description and accompanying drawings, in which:

### BRIEF DESCRIPTION OF THE DRAWINGS

FIG. 1 is a schematic diagram partially showing a perspective view of a packaged structure of a conventional light emitting module;

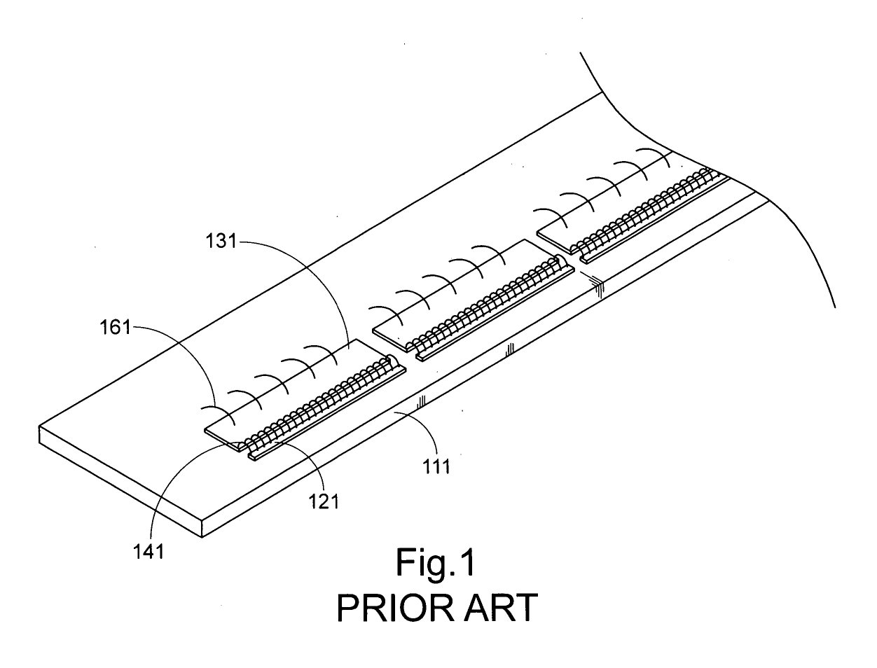

FIG. 2 is a schematic diagram showing a side view of the packaged structure of FIG. 1;

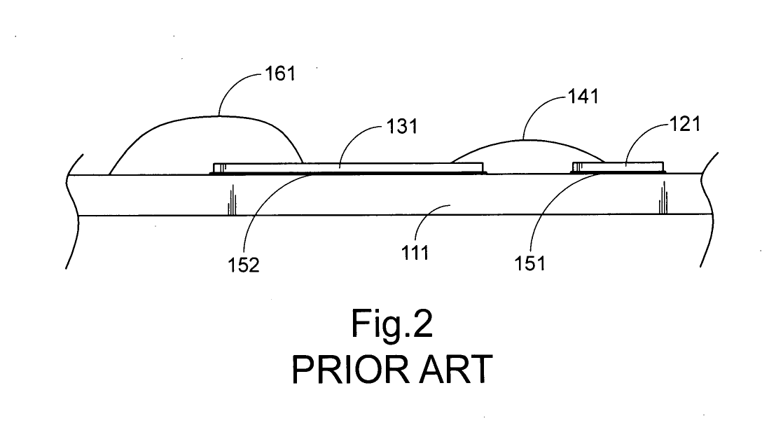

FIG. 3 is a schematic diagram partially showing a perspective view of a packaged structure of a light emitting module according to an embodiment of the present invention;

FIG. 4 is a schematic diagram showing a side view of the packaged structure of FIG. 3;

FIG. 5A is a resolving diagram schematically showing a top perspective view of an example of the light emitting module of FIG. 3;

FIG. 5B is a partially enlarged view of the portion A in FIG. 5A;

FIG. 6A is a schematic diagram showing a top perspective view of the assembled structure of FIG. 5A, in which the hidden wires are illustrated with dash lines;

FIG. 6B is a partially enlarged view of the portion B in FIG. 6A.

FIG. 7 is a schematic diagram partially showing a perspective view of a packaged structure of a light emitting module according to another embodiment of the present invention;

FIG. 8 is a schematic diagram showing a side view of the packaged structure of FIG. 7;

FIG. 9A is a resolving diagram schematically showing a top perspective view of an example of the light emitting module of FIG. 7;

FIG. 9B is a partially enlarged view of the portion C in FIG. 9A; and

FIG. 10 is a schematic diagram showing a top perspective view of the assembled structure of FIG. 9A, in which the hidden wires are illustrated with dash lines.

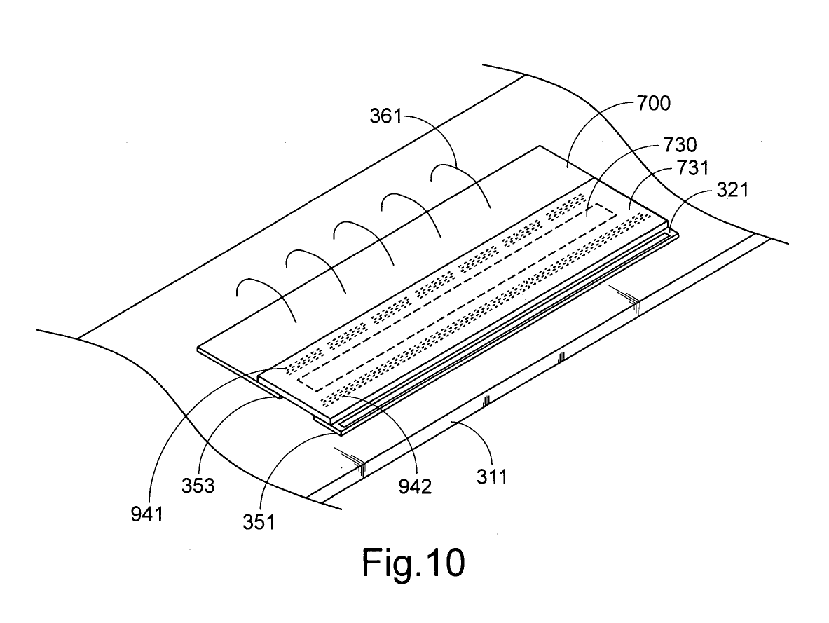

### DETAILED DESCRIPTION OF THE PREFERRED EMBODIMENT

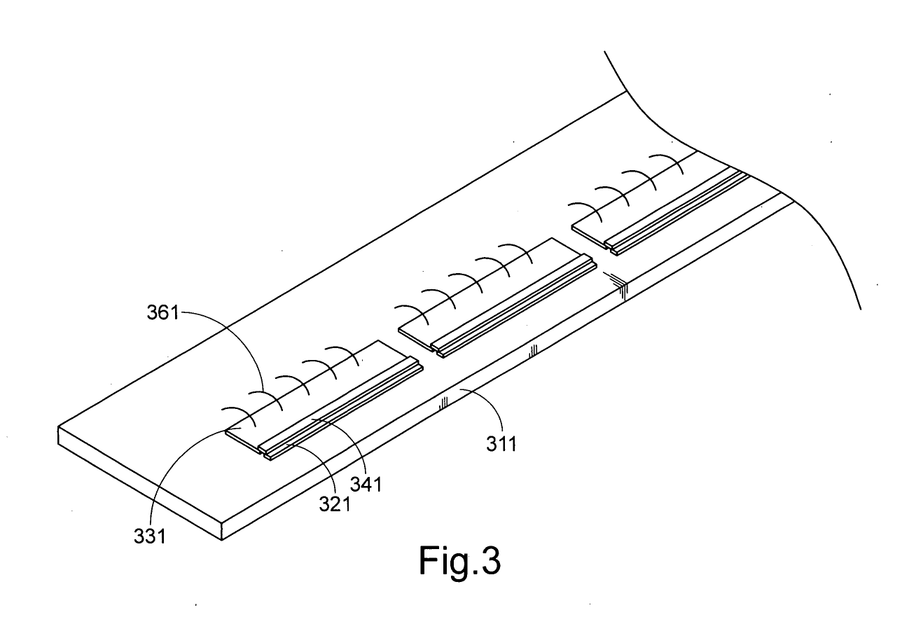

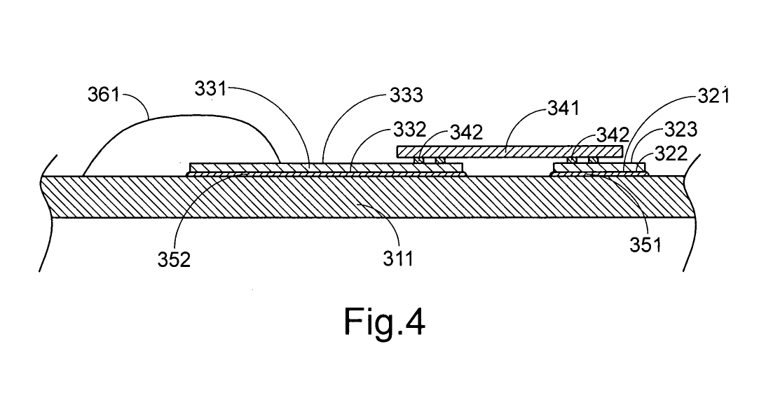

Referring to FIGS. 3 and 4, a packaged structure of an LED module according to an embodiment is partially shown. The LED module comprises a substrate 311, a plurality of light emitting elements 321, a plurality of driving circuit chips 331 and a plurality of flip-chip connectors 341. These light emitting elements 321 are adhered to the substrate 311 with adhesive material 351 and separate from one another for independently emitting light. The driving circuit chips 331 are adhered to the substrate 311 with adhesive material 352 and separate from one another for independently driving the light emitting elements 321. Via the flip-chip connectors 314, the driving circuit chips 331 are electrically connected to the light emitting elements 321 in a manner described as follows.

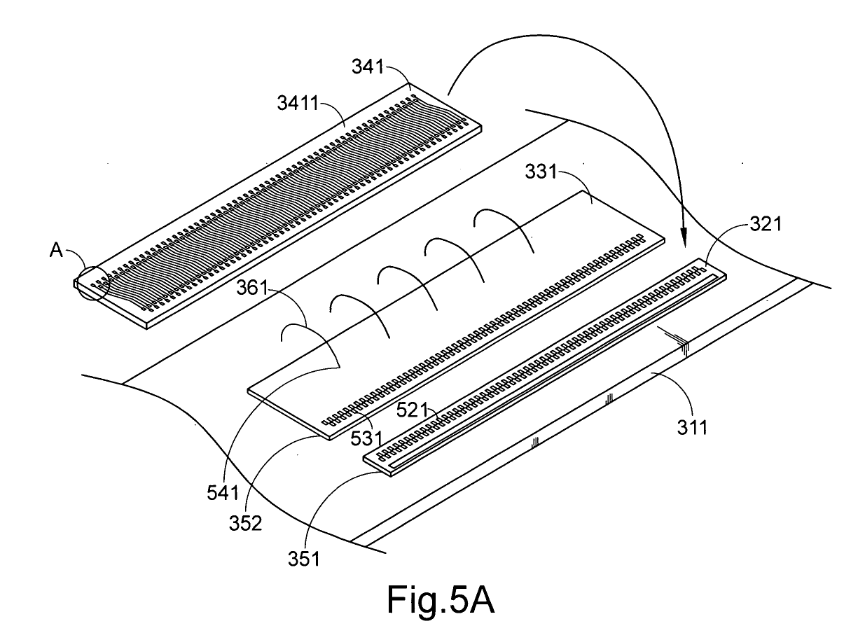

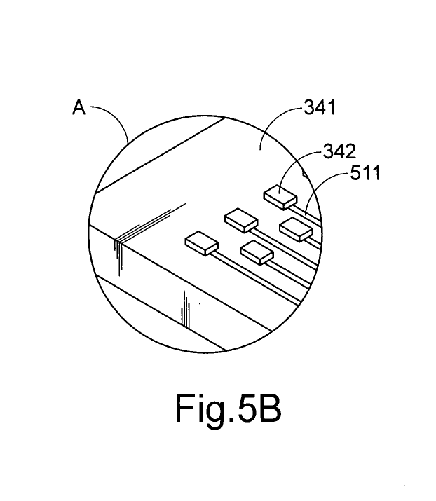

FIG. 5A is a resolving diagram schematically showing a top perspective view of an example of the LED module. The top surface of the driving circuit chip 331 comprises several bond pads 541 electrically connected to other elements on the substrate 311 via bonding wires 361. In addition, the top surface of the driving circuit chip 331 has thereon a plurality of bond pads 531 corresponding to bond pads 521 on the top surface of the light emitting element 321. As shown in the partial enlarged view of FIG. 5B, on the main body 3411 of the flip-chip connector 341, a plurality of wires 511 and a plurality of conductive bumps 342 electrically connected to the wires 511 are formed. The flip-chip connector 341, for example, can be is a circuit board formed thereon the conductive bumps 342 and wires 511.

The pads 521 of the light emitting element 321 and the pads 531 of the driving circuit chip 331 are electrically connected to each other one on one with individual wires 511 of the flip-chip connector 341. For minimizing the pitch between two adjacent wires 511, e.g. down to less than 50 micrometers, to enhance resolution, the conductive bumps 342 and the wires 511 of the flip-chip connector 341 can be produced by a micro-lithographic and etching process. Accordingly, a lithographically etched pattern is formed on the bottom surface of the main body of the flip-chip connector 341 as shown in FIG. 5A. Of course, other suitable techniques such as printing or ink-jetting can also be applied hereto to result in small but reliable pitches.

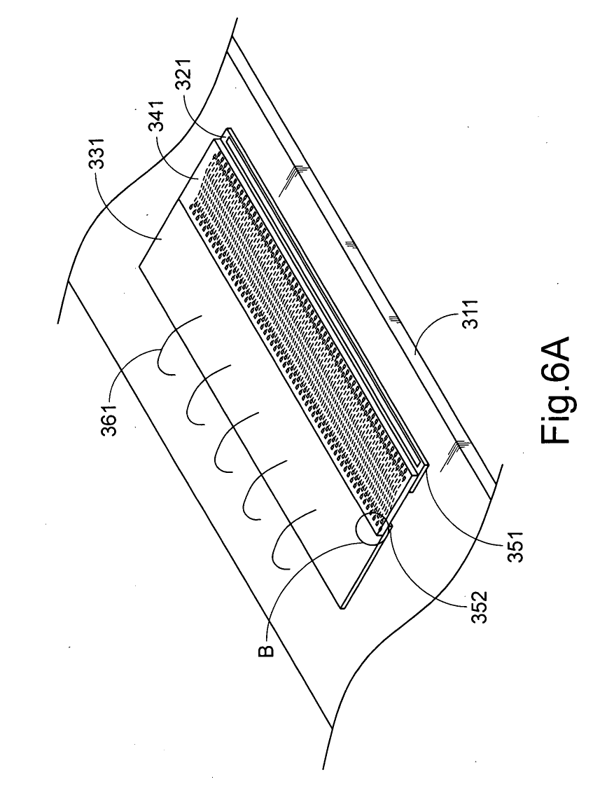

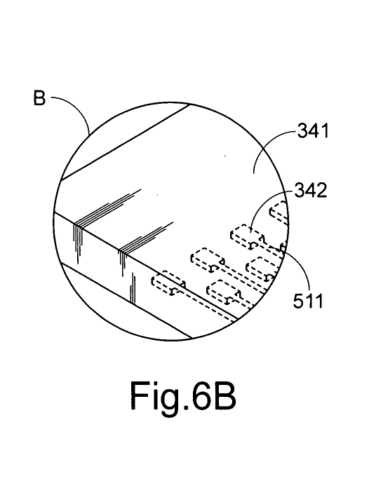

Please refer to FIGS. 6A and 6B. For assembling the LED module, the flip-chip connector 341 is firstly reversed and then put as a bridge between the driving circuit chip 331 and the light emitting element 321. It takes only 3˜5 seconds to accomplish the placement. Then, the alignment of the conductive bumps 342 with pads 521 or 531 is precisely performed. By making the conductive bumps 342 in contact with the pads 531 on the driving circuit chip 331 and the pads 521 on the light emitting element 321, the driving circuit chip 331 is communicable with the light emitting element 321 via the flip-chip connector 341.

The simplified process of manufacturing the LED module as mentioned above is advantageous of increasing yield, reliability and resolution of the product and reducing the manufacturing cost. Take an A4 size LED printer head for example. On the condition of a resolution of 600 dpi, it takes about 2 minutes only to assemble the LED module of the present invention. In contrast, it takes about 15 minutes to perform the wire boding operations 5,000 times according to prior art. In a case that the resolution is increased from 600 dpi to 1,200 dpi, while the assembling time of the wire bonding operations doubles in the prior art, the assembling time of the LED module of the present invention is hardly increased. Further, according to the present invention, the problem encountered by the prior art that the wire bonding density is too high to be practiced does not exist any longer.

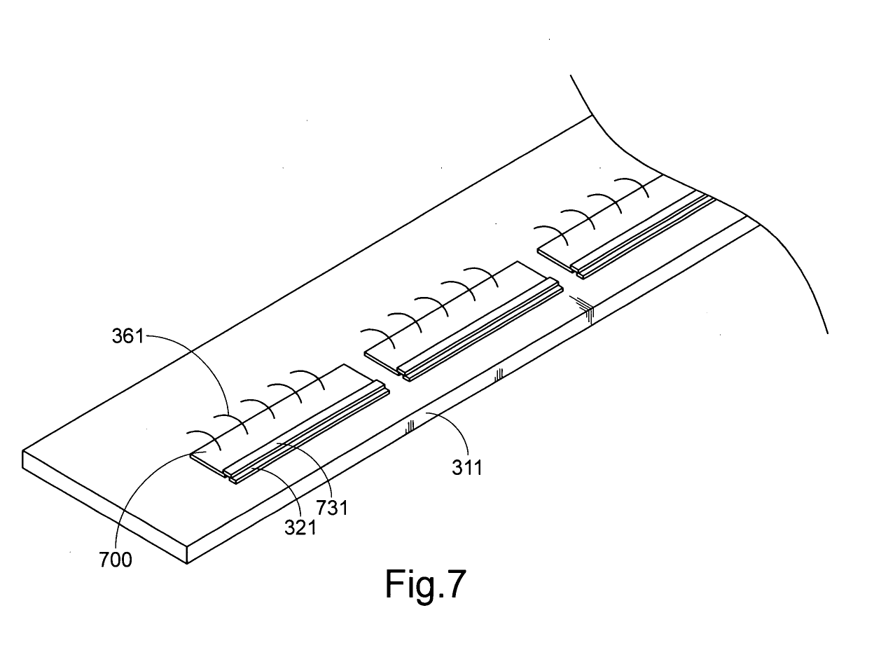

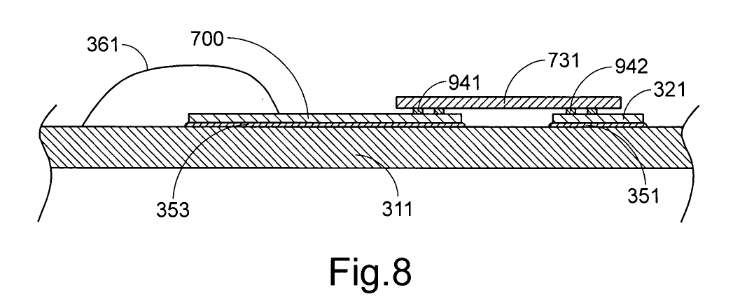

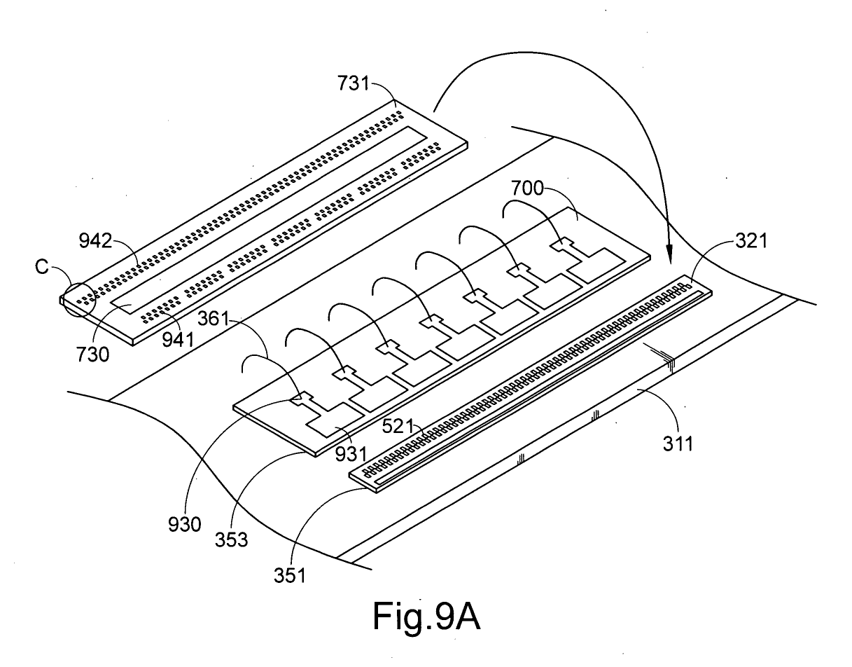

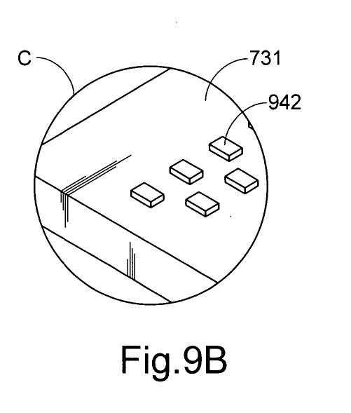

According to another embodiment of the present invention, the LED module is further advantageous of reducing the area of the driving circuit chips. Please refer to FIGS. 7 and 8, a packaged structure of an LED module according to another embodiment is partially shown. The LED module comprises a plurality of light emitting elements 32 adhered to the substrate 311 with adhesive material 351, a plurality of driving circuit chips 731 separate from one another for independently driving the light emitting elements 321, and a plurality of connectors 700 adhered to the substrate 311 with adhesive material 353. The driving circuit chips 731 used herein are of a flip-chip type and connecting to both of the light emitting elements 321 and the connectors 700. Via the connectors 700, the driving circuit chips 731 are further electrically connected to the other elements on the substrate 311. Further refer to FIG. 9A that is a resolving diagram schematically showing a top perspective view of an example of the LED module. The top surface of each of the light emitting element 321 is arranged with a plurality of pads 521. The top surface of each of the connectors 700 comprises two groups of pads 931 and 930, wherein the pads 930 are to be electrically connected to other elements on the substrate 311 via bonding wires 361. On the other hand, each of the flip-chip type driving circuit chips 731 includes two groups of conductive bumps 941 and 942 separated a certain distance from each other in addition to the main circuit 730. The flip-chip type driving circuit chip 731, for example, can be a circuit board formed thereon the conductive bumps 941 and 942 and main circuit 630 electrically interconnected. FIG. 9B schematically shows partial conductive bumps as an enlarged view of the portion C of FIG. 9A. After each flip-chip type driving circuit chip 731 is turned and attached to the substrate 311, the conductive bumps 941 and 942 thereof are electrically connected to the pads 931 of the connector 700 and the pads 521 of the light emitting element 321, respectively.

As mentioned above, the pads 521 of the light emitting elements 321 and the conductive bumps 942 of the driving circuit chips 731 are electrically connected to each other one on one. On the other hand, the driving circuit chips 731 are electrically connected to other elements on the substrate 311 via the conductive bump groups 941, the pads 931 and 930 of the connectors 700 and the boding wires 361. In this way, the driving circuit chips 731 can communicate with and control the light emitting elements 321 and also are communicable with other elements on the substrate 311.

Like the first embodiment mentioned above, the LED module including the flip-chip type driving circuit chips allows a reduced pitch as small as less than 50 micrometers because the circuit can be produced by a micro-lithographic and etching process, or alternatively printing or ink-jetting process. Meanwhile, the assembly is easy and efficient because no wire bonding operation between the light emitting elements and the driving circuit chips is required. Further, compared to the prior art that the area of bonding pads generally occupy most of the area of an LED device, the size of the LED device can be reduced up to 30% by using the flip chip mounting means of the present invention. Thus, the material cost can be saved significantly.

In spite the embodiments of the present invention are illustrated with LED modules, other light emitting modules such as LCD devices or laser emitting modules can also use the present flip-chip mounting means to achieve the purposes of enhanced resolution, easy assembling and reduced size. For use in an image processing apparatus such as printing machines, copying machines or scanning machines, the substrate mentioned above can be a printed circuit board or a ceramic substrate, and the light emitting element can be a light emitting diode, a liquid crystal display element or a laser light source element.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A light emitting module, comprising:
a substrate;
a driving circuit chip attached to said substrate;
a light emitting element attached to said substrate; and
a flip-chip connector having a plurality of conductive bumps and wires for electrically connecting to both said driving circuit chip and said light emitting element when said flip-chip connector is placed above said driving circuit chip and said light emitting element as a bridge, thereby communicating said driving circuit chip with said light emitting element.

2. The light emitting module according to claim 1 wherein said substrate is a printed circuit board or a ceramic substrate.

3. The light emitting module according to claim 1 wherein said light emitting element is a light emitting diode, a liquid crystal display element or a laser light source element, and said light emitting module is for use in a printing machine, a copying machine or a scanning machine.

4. The light emitting module according to claim 1 wherein said conductive bumps of said flip-chip connector are in direct contact with bond pads of said driving circuit chip and bond pads of said light emitting element.

5. The light emitting module according to claim 1 wherein said flip-chip connector is a circuit board formed thereon said conductive bumps and wires.

6. A light emitting module, comprising:
a substrate;
a driving circuit chip having a first surface attached to said substrate and a second surface having thereon a plurality of first contacts;
a light emitting element having a third surface attached to said substrate and a fourth surface having thereon a plurality of second contacts; and
a bridge connector comprising a main body and a plurality of wires supported by said main body, said wires electrically connecting said first contacts to said second contacts one on one when said bridge connector is coupled to said driving circuit chip and said light emitting element, thereby communicating said driving circuit chip with said light emitting element.

7. The light emitting module according to claim 6 wherein said bridge connector further comprises a plurality of conductive bumps electrically connected to said wires, and said bridge connector is coupled to said driving circuit chip and said light emitting element by contacting said conductive bumps with said first contacts and said second contacts.

8. The light emitting module according to claim 7 wherein said bridge connector is a flip-chip connector, and said conductive bumps and said wires are arranged on the bottom surface of said main body.

9. The light emitting module according to claim 8 wherein said conductive bumps and said wires are included in a lithographically etched pattern formed on the bottom surface of said main body.

10. The light emitting module according to claim 6 wherein said driving circuit chip has third contacts wired to said substrate on said second surface.

11. The light emitting module according to claim 6 wherein a pitch between two adjacent ones of said wires is less than 50 micrometers.

12. The light emitting module according to claim 6 wherein said driving circuit chip and said light emitting element are attached to said substrate with adhesive material.

13. A light emitting module, comprising:
a substrate;
a light emitting element attached to said substrate;
a connector attached to said substrate; and
a flip-chip type driving circuit chip having a main circuit for controlling said light emitting element and a plurality of conductive bumps electrically connecting to both said light emitting element and said connector when said flip-chip type driving circuit chip is placed above said light emitting element and said connector as a bridge, thereby communicating said main circuit with said light emitting element and said connector.

14. The light emitting module according to claim 13 wherein said flip-chip type driving circuit is a circuit board formed thereon said main circuit and said conductive bumps electrically interconnected.

15. The light emitting module according to claim 13 wherein said light emitting element and said connector further comprise a plurality of bond pads in direct contact with said conductive bumps of said flip-chip type driving circuit chip, respectively, when said flip-chip type driving circuit chip is placed above said light emitting element and said connector as said bridge.

16. The light emitting module according to claim 13 wherein said conductive bumps are formed by a lithographic and etching process along with said main circuit.

17. The light emitting module according to claim 13 wherein said substrate is a printed circuit board or a ceramic substrate.

18. The light emitting module according to claim 13 wherein said light emitting element is a light emitting diode, a liquid crystal display element or a laser light source element, and said light emitting module is for use in a printing machine, a copying machine or a scanning machine.

19. The light emitting module according to claim 13 wherein said connector comprises a plurality of bond pads wired to said substrate.

20. The light emitting module according to claim 13 wherein a pitch between two adjacent ones of said conductive bumps is less than 50 micrometers.
